(19) United States
(12) Patent Application Publication
(10) Pub. No.: US 2007/0176239 A1
(43) Pub. Date: Aug. 2, 2007

(54) Trenched MOSFETS with improved ESD protection capability

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Semiconductor Sdn. Bhd.

(21) Appl. No.: 11/344,811

(22) Filed: Jan. 31, 2006

(51) Int. Cl. H01L 23/62

(52) U.S. Cl. 257/355

(57) ABSTRACT

A semiconductor power device includes Zener diodes for providing an electrostatic discharge (ESD) protection. The semiconductor power device further includes a thick insulation layer for substantially insulating the Zener diodes from a doped region doped with the body dopant ions of the semiconductor power device whereby the Zener diode is substantially insulated from a doped region below the thick insulation layer for eliminating a channel effect between two terminals of the Zener diode disposed above the doped region. The Zener diode further includes an array of doped regions comprising doped regions doped alternately with a first conductivity type and a second conductivity type with a first and last doped regions doped with a first conductivity type. Specifically, the Zener diode may include an array of doped regions comprising doped regions arranged as N+PN+PN+ regions. Alternately, the Zener diode may include an array of doped regions comprising doped regions arranged as N+PN+PN+PN+ regions.

### BACKGROUND OF THE INVENTION

1. Field of the Invention

This invention relates generally to the cell structure, device configuration and fabrication process of power semiconductor devices. More particularly, this invention relates to a novel and improved cell configuration and processes to manufacture MOSFET device with an improved electrostatic discharge (ESD) protection having symmetrical current-voltage (I-V) operational characteristics with symmetrical Zener diode breakdown voltage and robust gate pad contact area for ESD protection.

2. Description of the Related Art

Conventional technologies still have technical difficulties in dealing with the electrostatic discharge (ESD) problems in designing, manufacturing and implementing the semiconductor power devices. Specifically, the high voltage transient signal from static discharge in a DMOS device can impose a voltage bias higher than 10,000 volts. The high electric field induced by the bias voltage when imposed on a relatively thin layer of gate dielectric layer often leads to hazardous conditions to the DMOS device. The thin layer of gate dielectric is most commonly implemented as an oxide layer. Under a high electric field, rapture is induced in the oxide layer that functions as an insulator. A permanent damage is thus introduced into a system implemented with the power semiconductor device. The reliability of system performance and operations suffer due this ESD problem. This problem is particularly pronounced in high voltage DMOS devices. Many ESD protective measures are implemented. DMOS devices are often designed and manufactured with self-contained ESD protection systems. The ESD protection circuits can be implemented either as a discrete circuit or as an integrated part of the semiconductor power devices. One of such methods is disclosed in U.S. Pat. No. 5,602,046. A Zener diode is connected between the gate and the source of a DMOS device to protect the gate of the device from a voltage above an oxide breakdown voltage. The over-voltage damages caused by EDS are prevented. However, the ESD protection configuration disclosed by this patent requires additional mask and thus significantly increasing the production cost of such devices.

In U.S. Pat. Nos. 6,657,256 and 6,664,683, a device and method are disclosed to provide over-voltage protection in a DMOS transistor shown in FIG. 1A. The DMOS transistor 10 includes a substrate 12 with an epitaxial layer 15 of a first conductivity type and a body region 20 of a second conductivity type formed over the substrate. At least one trench 25 extends through the body region 20 and the substrate 15. An insulating layer 30 lines the trench and overlies the body region. A conductive electrode 25 is deposited in the trench so that it overlies the insulating layer. A source region 35 of the first conductivity type is formed in the body region adjacent to the trench 25. The over-voltage protection is provided by forming an undoped polysilicon layer 40 overlies a portion of the insulating layer 35. Several cathode regions 45 of the first conductivity type are formed in the undoped polysilicon layer 40. At least one anode region 50 is in contact with adjacent ones of the plurality of cathode regions 45.

Referring to FIG. 1B, the over-voltage protection configuration presents a disadvantage. As shown in FIG. 1C, the device has a nonsymmetrical I-V characteristics. A high current Igss from the bottom of the anode P region 50 causes the nonsymmetrical I-V characteristics. When a negative gate bias is applied, negative charges are formed in the bottom of the p region 50 when the oxide layer 35 underneath the polysilicon layer 40 is a gate oxide (GOX) thin oxide layer. The negative charges formed underneath the p region 50 leads to a channeling effect with significantly increased current. The nonsymmetrical I-V characteristics stand for different breakdown voltage of Zener diode at positive and negative polarities. The Zener diode breakdown voltage BVzener is required to be less than Bvox (gate oxide rupture voltage) to ensure the electrostatic charge goes through ESD diode first when the gate bias exceed BVzener instead of gate oxide for gate oxide protection. If BVzener is not same or close enough at different polarities, ESD diode only can protect negative electrostatic charge not positive electrostatic charge. In this case, it is necessary make BVzener low enough for both polarities. However, leakage current between gate and source Igss will be high, and exceed industrial specification, causing more battery power consumption. Moreover, the ESD capability is not stable since the gate oxide thickness and the P doping variations also control the ESD protection function.

Another disadvantage of prior arts is the existence of weak spot at gate pad contact due to a thin layer of the gate oxide. Electrostatic charge may goes vertically through gate pad contact and gate oxide area first, then through ESD diode. The gate oxide is easily damaged before the ESD protection function provided by the Zener diode is turned on.

Therefore, there is still a need in the art of the semiconductor device fabrication, particularly for trenched power semiconductor design and fabrication, to provide a novel cell structure, device configuration and fabrication process that would resolve these difficulties and design limitations. Specifically, it is desirable to provide effective over-voltage protection to reduce a likelihood of device damages caused by ESD. In the meantime, it is also desirable to eliminate the problems caused by the nonsymmetrical current voltage (IV) characteristics due to the implementation of the Zener diode. Additionally, it is desirable to overcome the problems caused by the weak spot due to the presence of a thin oxide layer disposed underneath the Zener diode.

### SUMMARY OF THE PRESENT INVENTION

It is therefore an aspect of the present invention to provide new and improved semiconductor power device configuration and manufacture processes for electrostatic discharge (ESD) protection. The Zener diode integrated with the semiconductor power device is insulated from the doped region of the semiconductor power device to prevent a channeling effect. The problems of nonsymmetrical operational characteristics of the power device are therefore eliminated.

Briefly, in a preferred embodiment, the present invention discloses a semiconductor power device comprising a Zener diode connected between a gate metal and a source metal of said MOSFET device for providing an electrostatic discharge (ESD) protection. The semiconductor power device further includes a thick insulation layer with a thickness greater than gate oxide for completely insulating the Zener diode from a doped region of body dopant ions whereby the Zener diode is substantially insulated from a doped region below the thick insulation layer for eliminating a channel effect between two terminals of the Zener diode disposed above the doped region. In a preferred embodiment, the thick insulation layer includes a thick oxide layer having a thickness substantially greater than five hundred (500) Angstroms. In another preferred embodiment, the thick insulation layer includes a separately formed thick insulation layer on top of a gate oxide layer. In another preferred embodiment, the Zener diode further includes multiple doped regions having at least a middle region doped with a first conductivity type disposed between two regions doped with a second conductivity type. In another preferred embodiment, the Zener diode further includes a doped region of a second conductivity type disposed between two doped regions of a first conductivity type wherein one of the two doped regions connected to the source metal and another one of the two doped regions connected to the gate metal of the semiconductor power device. In another preferred embodiment, the semiconductor power device further includes an overlying insulation layer covering the semiconductor power de vice and the Zener diode wherein the overlying insulation layer having a plurality of contact openings having at least two of the contact openings filled with the source metal to contact a source region and a first terminal of the Zener diode. At least one of the contact openings filled with the gate metal for contacting to a gate and a second terminal of the Zener diode. In another preferred embodiment, the semiconductor power device further includes an overlying insulation layer covering the semiconductor power de vice and the Zener diode wherein the overlying insulation layer having a plurality of trenched contact plugs disposed in trenches penetrating through the insulation layer wherein some of the contact plugs are in electrical contact with a source region and the source metal and a first terminal of the Zener diode and other of the trenched plugs are in electric contact with a gate and the gate metal and also with a second terminal of the Zener diode. In another preferred embodiment, the trenched contact plugs further include tungsten contact plugs. In another preferred embodiment, the trenched contact plugs further includes tungsten contact plugs surrounded by a Ti/TiN barrier layer. In another preferred embodiment, the trenched contact plugs further includes an extended continuous contact plug constituting a closed stripe contact plug. In another preferred embodiment, the trenched contact plugs further includes at least one extended continuous contact plugs constituting open stripes. In another preferred embodiment, the Zener diode further includes a p-type doped region disposed between two n-type doped regions wherein one of the n-type doped regions connected to the source metal and another of n-type doped regions connected to the gate metal of the semiconductor power device. In another preferred embodiment, the semiconductor power device further includes a doped region electrically connected between the Zener diode and the gate metal serving a resistor function for slowing down an ESD current charge flow through a gate of the semiconductor power device. In another preferred embodiment, the semiconductor power device further comprises a metal oxide semiconductor field effect transistor (MOSFET) device. In another preferred embodiment, the semiconductor power device further includes an additional Zener diode as a second Zener diode disposed also on the thick insulation layer as the Zener diode as a first Zener diode wherein the second Zener diode serving an extra ESD protection for the semiconductor power device to receive ESD charges after the first Zener diode is burnt out by the ESD charges. In another preferred embodiment, the semiconductor power device further includes a doped region electrically connected between the first Zener diode and the second Zener diode and electrically connecting to the gate metal serving a resistor function for slowing down an ESD current charge flow through a gate of the semiconductor power device. In another preferred embodiment, the Zener diode further includes an array of doped regions includes doped regions doped alternately with a first conductivity type and a second conductivity type with a first and last doped regions doped with a first conductivity type. In another preferred embodiment, the Zener diode further includes an array of doped regions includes doped regions arranged as N+PN+PN+ regions. In another preferred embodiment, the Zener diode further includes an array of doped regions includes doped regions arranged as N+PN+PN+PN+ regions.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a side cross sectional view of a conventional MOSFET device with Zener diode formed in a Zener polysilicon layer supported on top of a thin oxide layer.

FIGS. 1B is a side cross sectional view of the conventional Zener diode of FIG. 1A and 1C is an I-V diagram having a nonsymmetrical characteristic due to the channeling effects shown in FIG. 1B.

FIG. 2A is a side cross sectional view of an improved MOSFET device with Zener diode formed in a Zener polysilicon layer supported on top of a separately formed thick oxide layer.

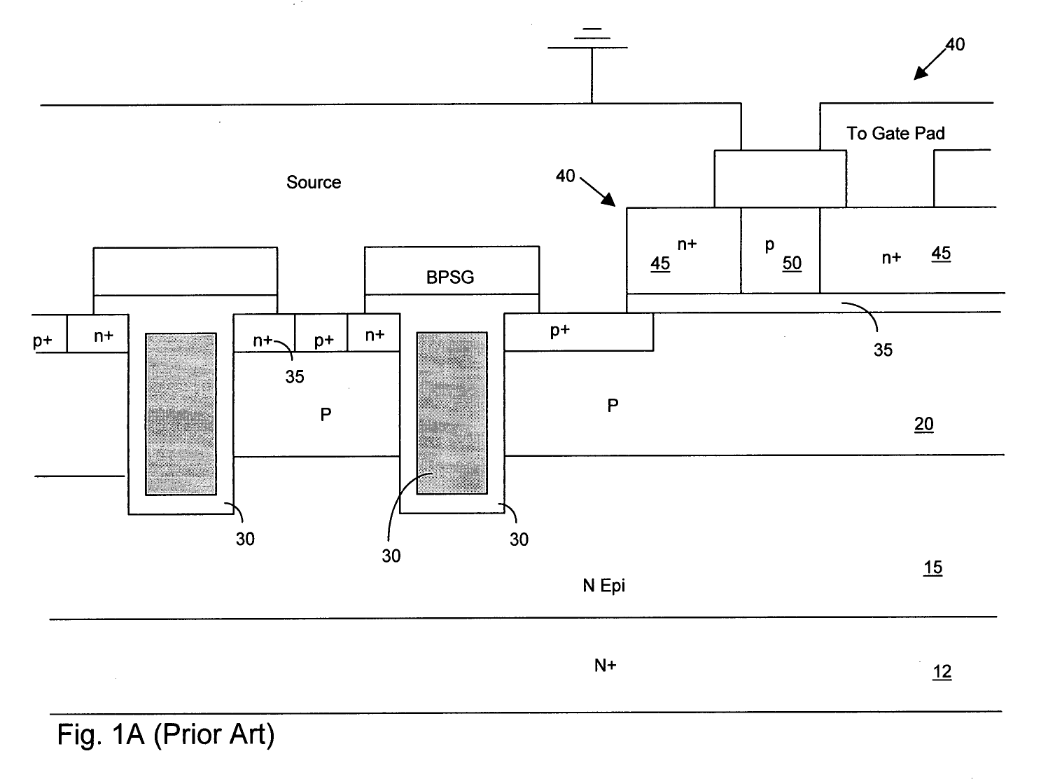

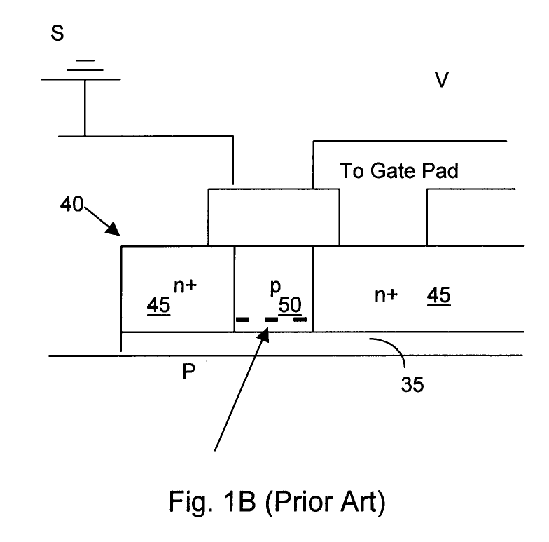

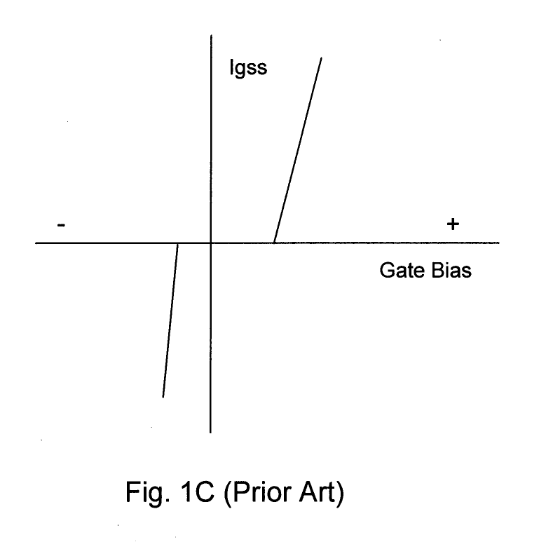

FIGS. 1B is an I-V diagram having a symmetrical characteristic because the channeling effects are eliminated by the separately formed thick oxide layer.

FIGS. 3A and 3B are respectfully two side cross sectional views of two alternate preferred embodiments of the MOSFET with improved Zener diodes of this invention.

FIGS. 4 and 5 are two top views to illustrate respectively close and open strips of source and gate metal contacts for the Zener diodes for ESD protection.

FIG. 6A to 6E are equivalent circuit diagrams and corresponding top views respectively of the MOSFET devices with different types of ESD protections.

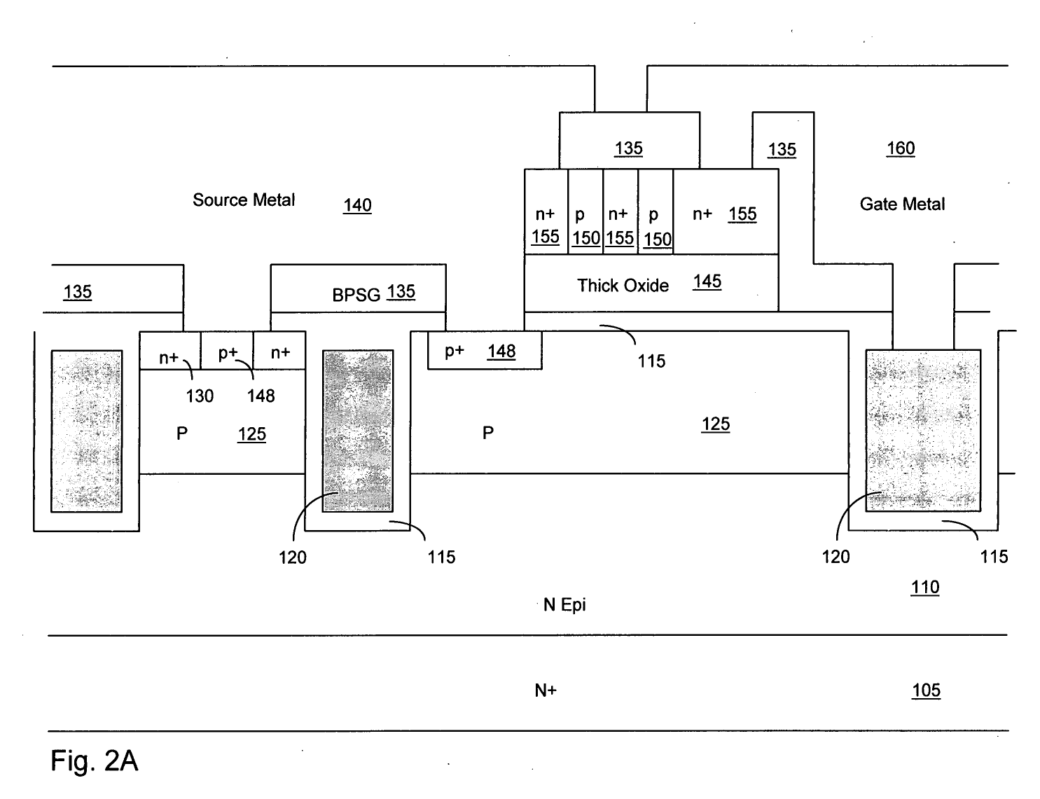

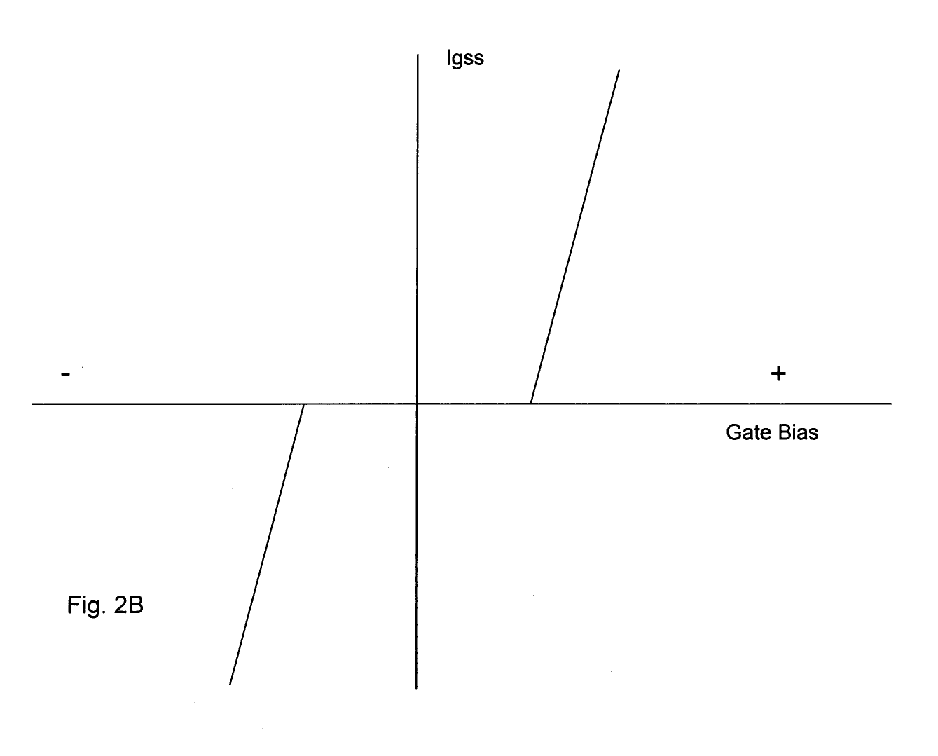

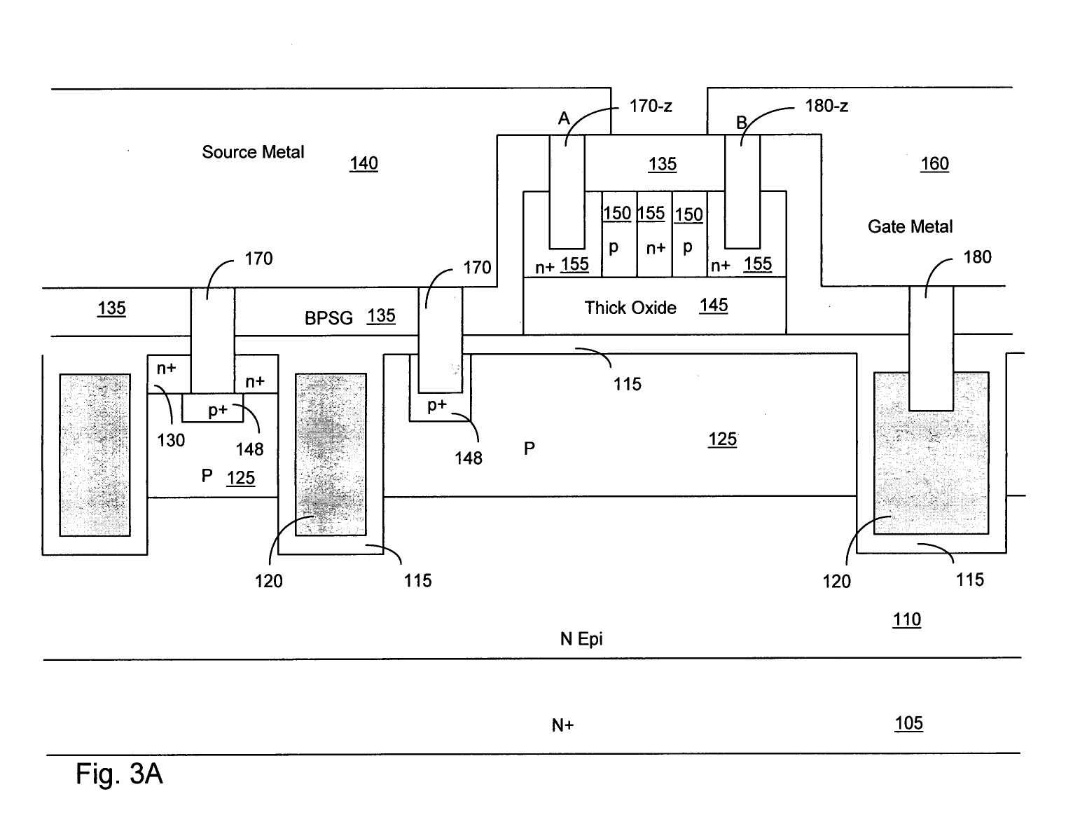

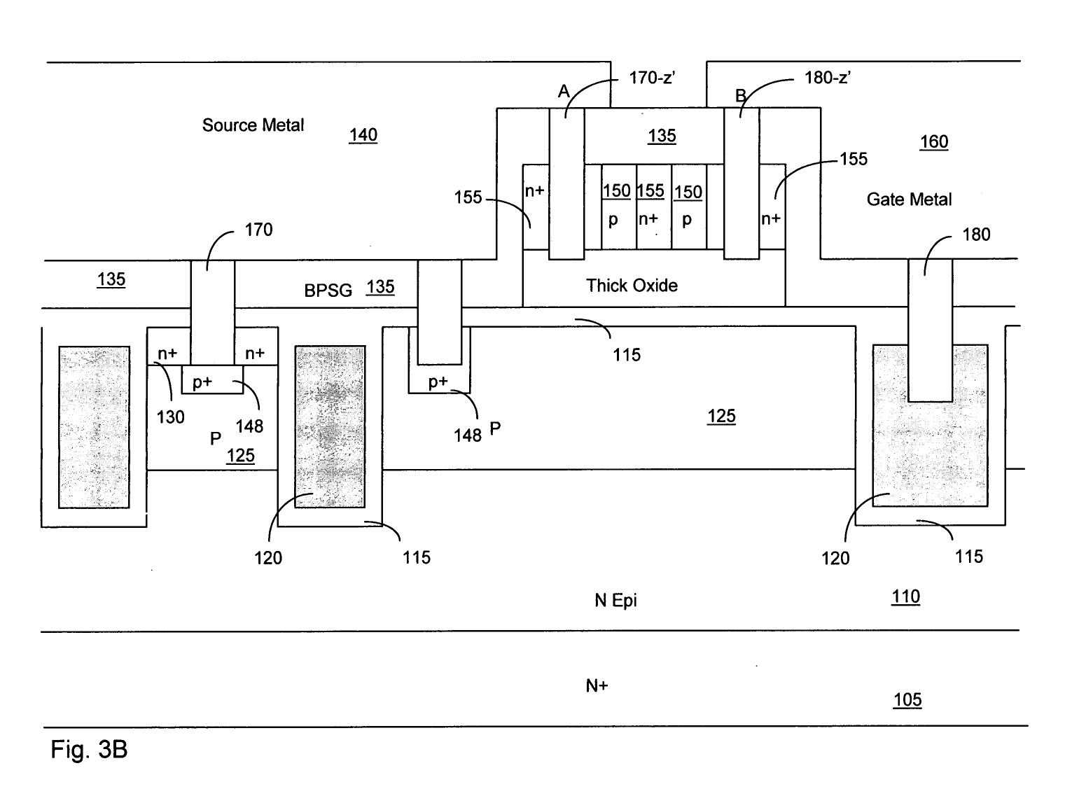

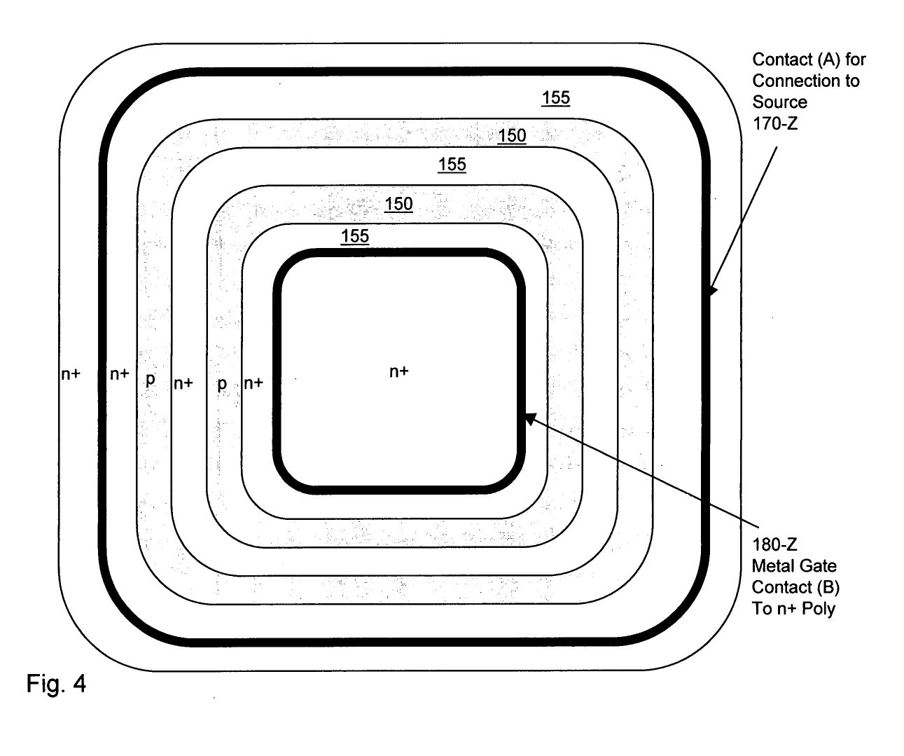

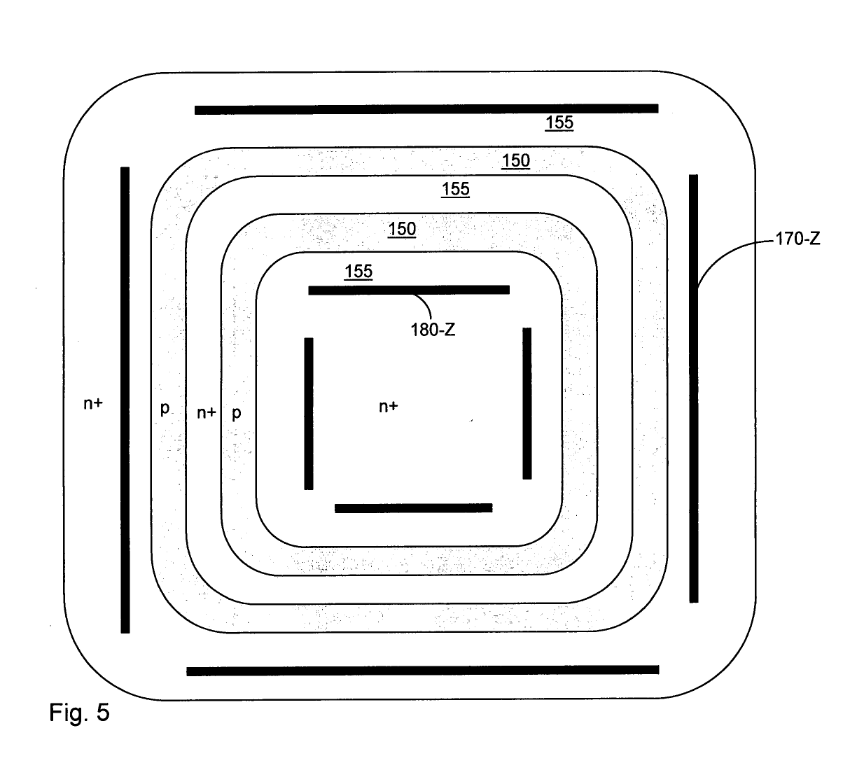

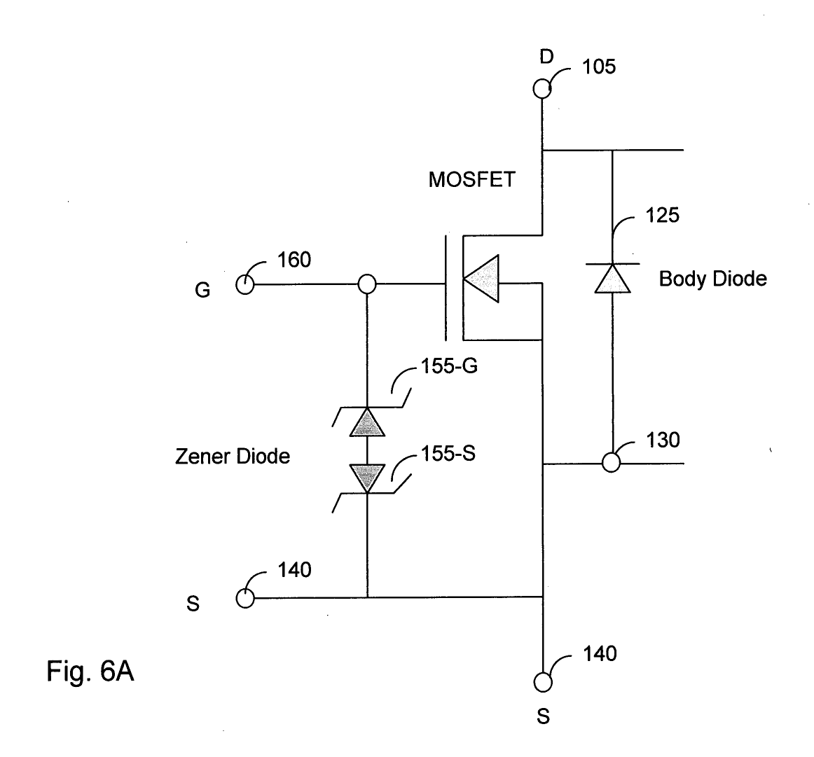

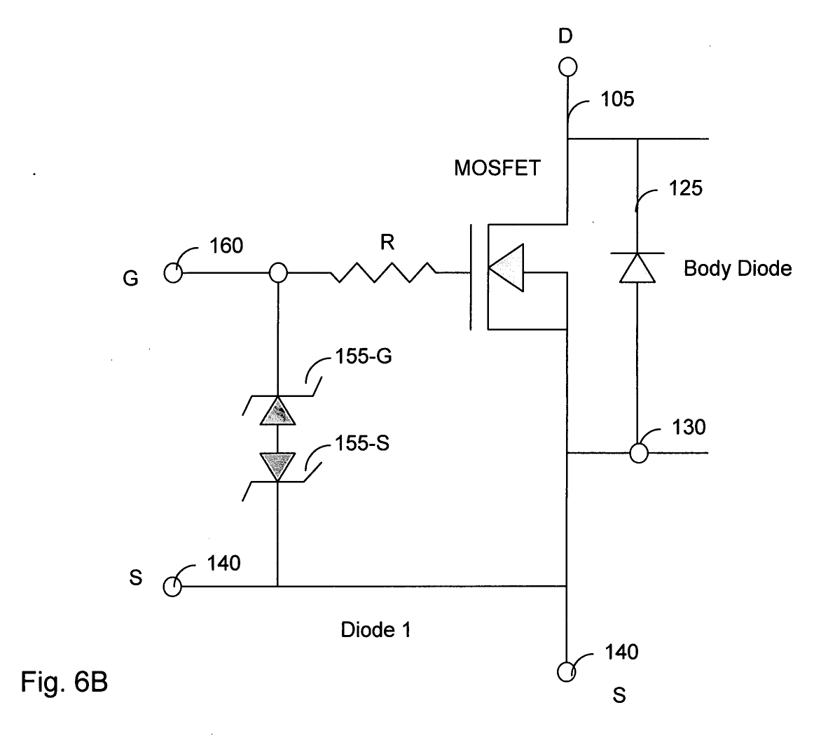

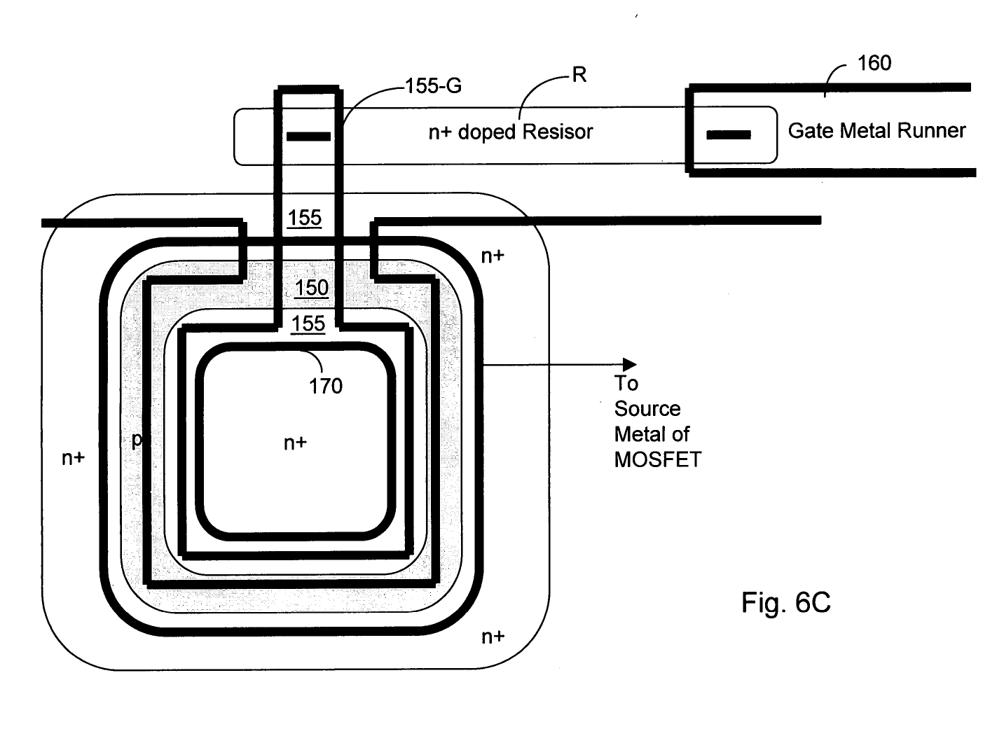

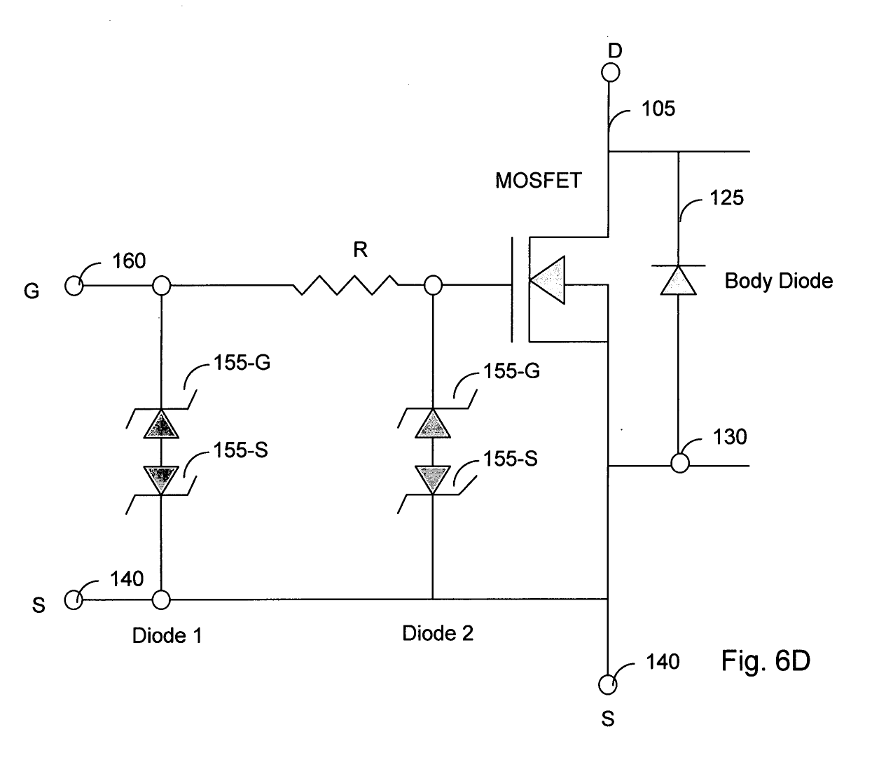

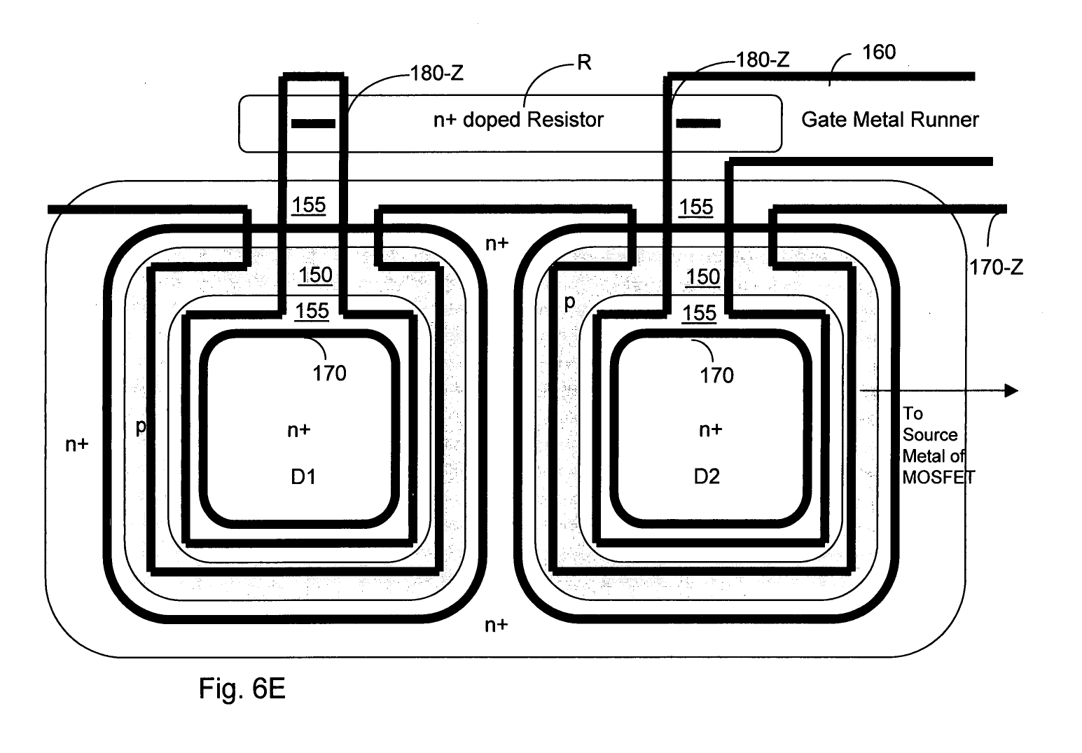

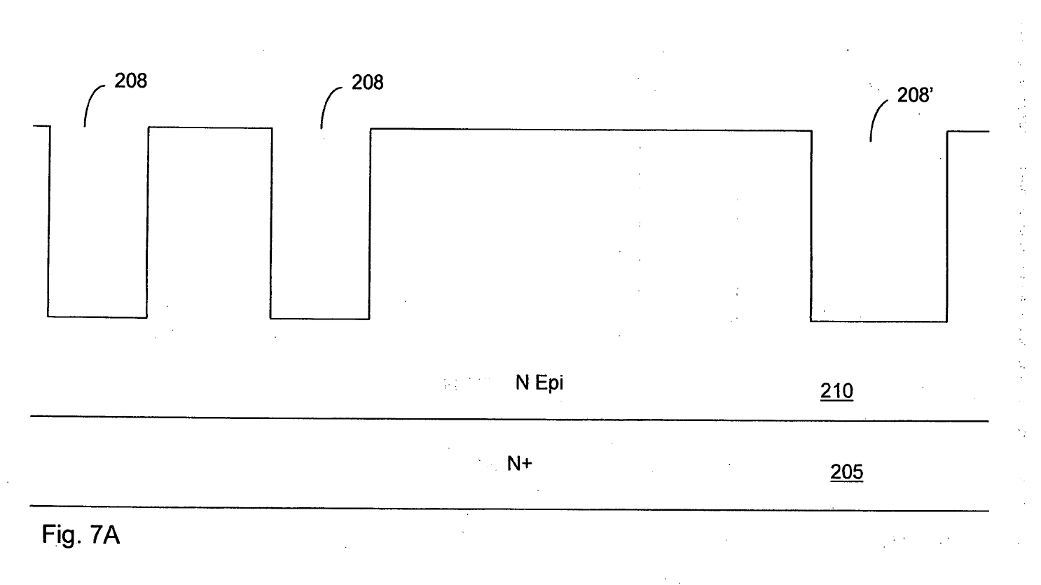

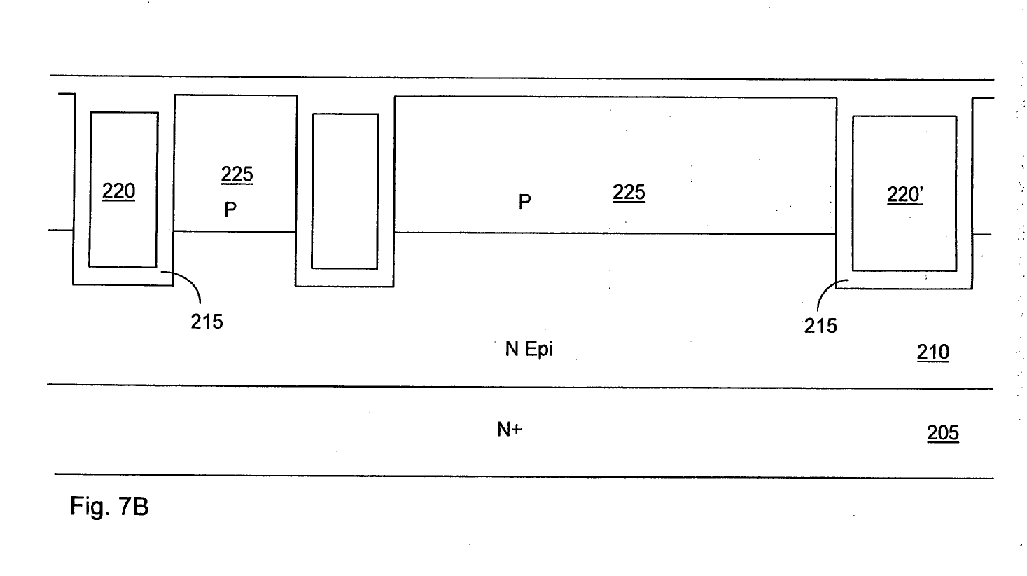

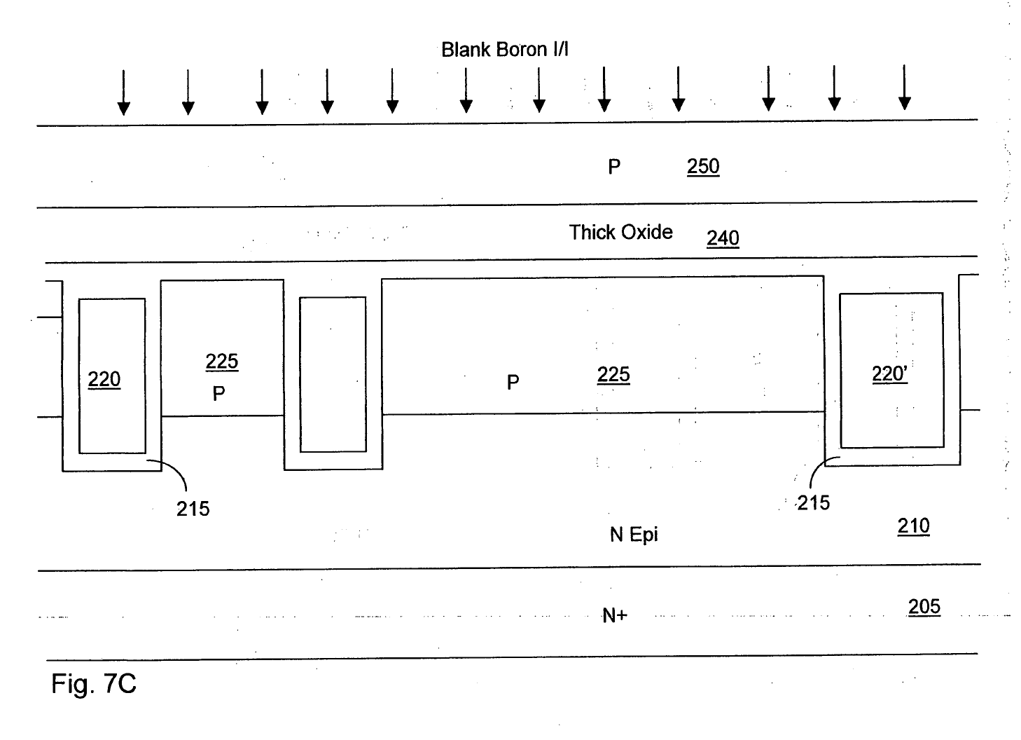

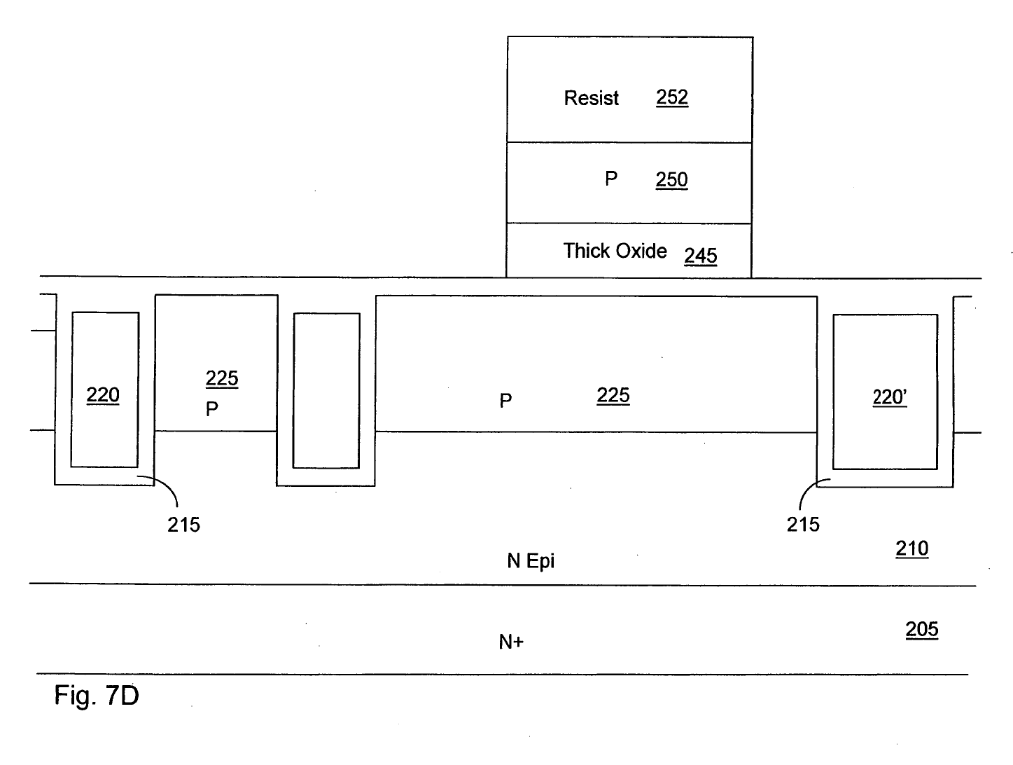

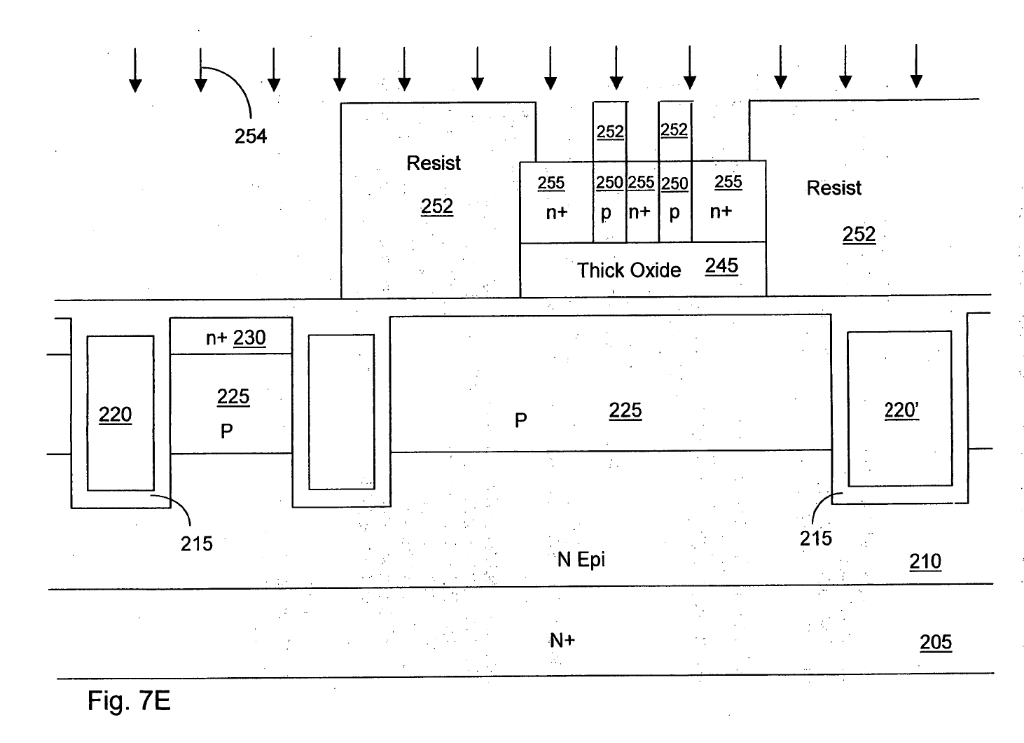

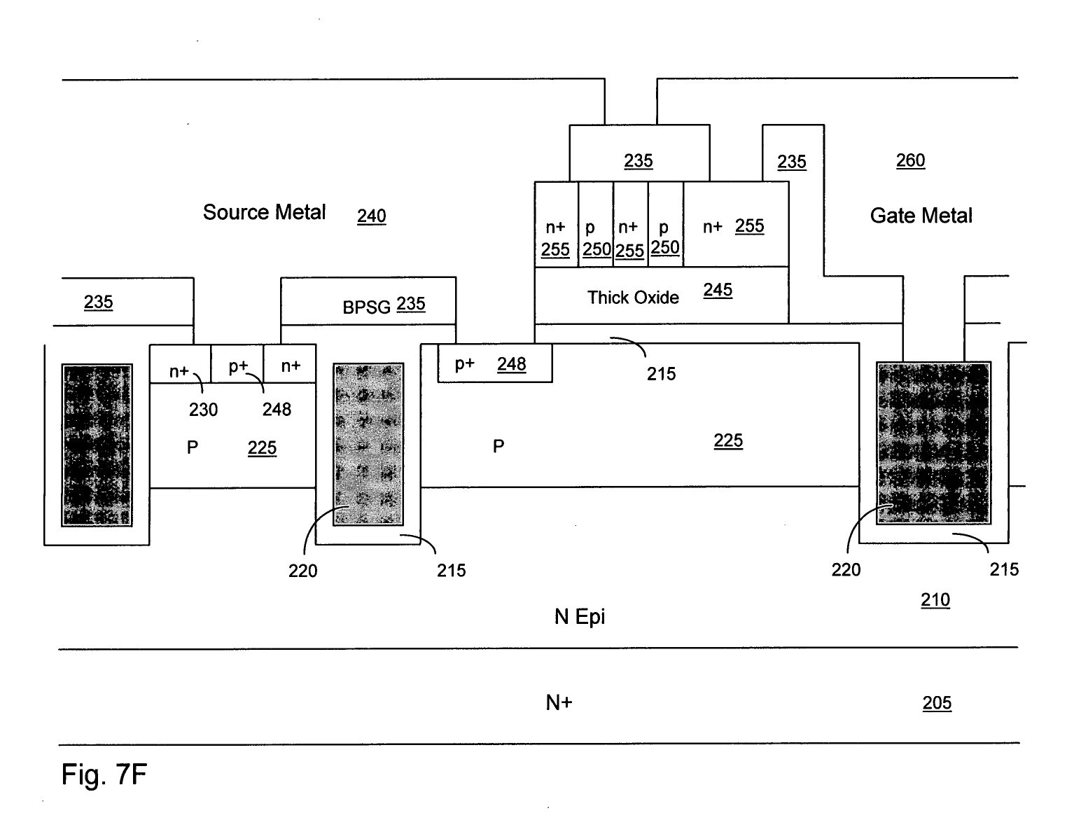

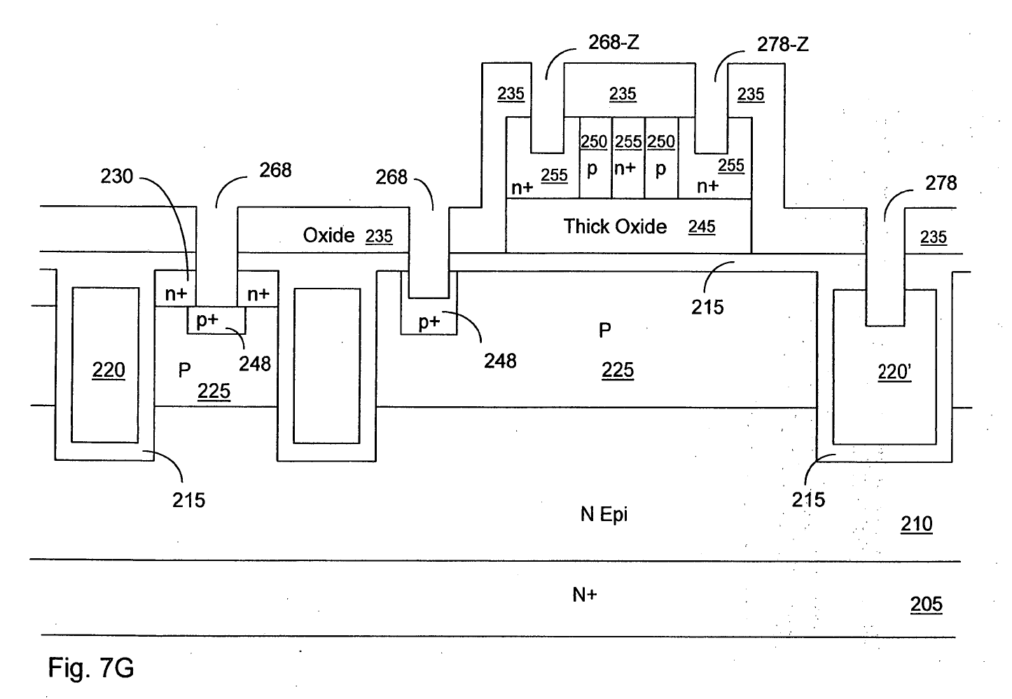

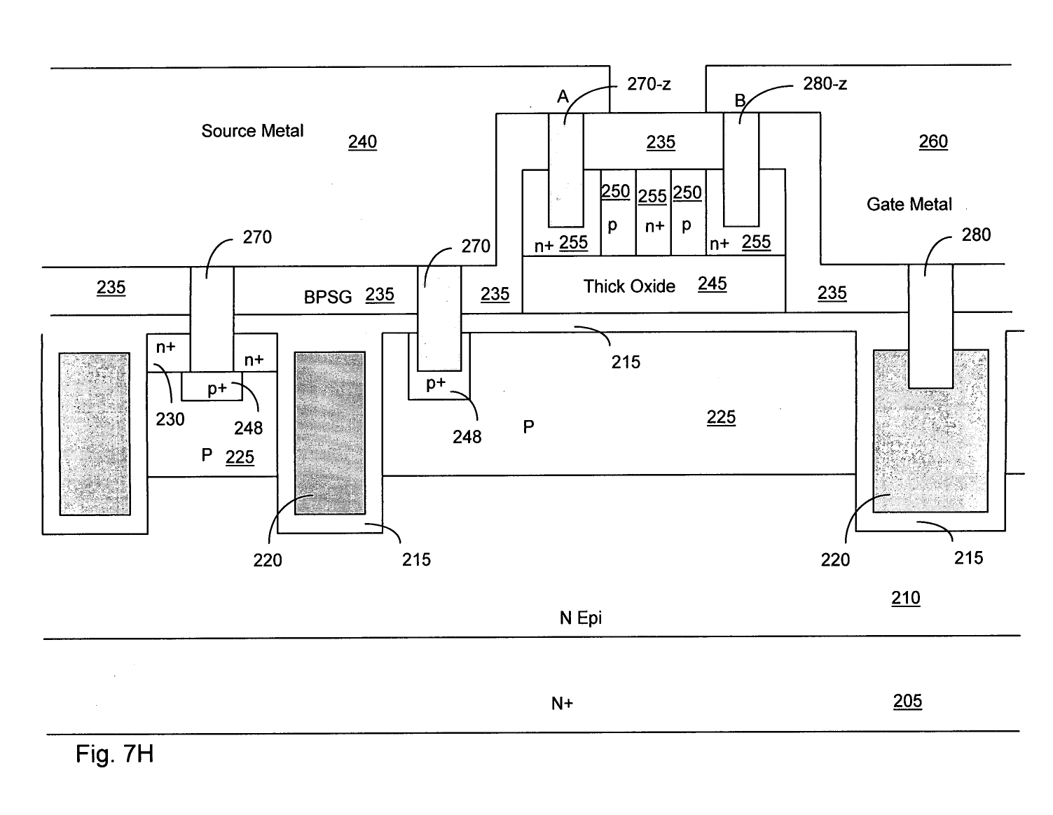

FIGS. 7A to 7F are a serial of side cross sectional views for showing the processing steps for fabricating a MOSFET device as shown in FIGS. 2A.

FIGS. 7G to 7H are two side cross sectional views for showing the processing steps for fabricating a MOSFET device as shown in FIG. 3A (or 3B) to place the gate and source contact plug in the trenched source and gate contact openings.

### DETAILED DESCRIPTION OF THE PREFERRED EMBODIMENT

Please refer to FIGS. 2A to 2B for the side cross sectional view and I-V diagram of a first preferred embodiment of this invention. FIG. 2A shows a metal oxide semiconductor field effect transistor (MOSFET) device 100 supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 120. The top surface of the semiconductor substrate extending over the top of the trenched gate, the P body regions 125 and the source regions 130 are covered with a NSG and a BPSG protective layers 135. A source metal layer 140 and gate metal layer (not shown) are formed on top of the protective insulation layer 135. For the purpose of improving the source contact to the source regions 130, the P+ doped source contact regions 148 is formed between the source regions 130 near the surface of the substrate under the source contact opening for electrically contacting source metal 140.

For the purpose of providing over-voltage ESD protection, a Zener diode is formed at the peripheral area of the MOSFET device. The Zener diode is supported on a thick oxide layer 145. The Zener diode includes a polysilicon layer formed with p-type doped regions 150 disposed next to n-type doped regions 155. One of the n-doped regions 155 is electrically connected to the gate through the gate metal layer 160. The thick oxide layer 145 underneath the Zener diode suppresses the channeling effect from the p-regions 125 underneath the Zener polysilicon layer 150. By insulating the p-type region 125 from the Zener diode, the MOSFET transistor now has symmetric current voltage (I-V) characteristics as that shown in FIG. 2B.

FIGS. 3A and 3B are cross sectional views for showing two different MOSFET devices 100-1 and 100-2 as alternate preferred embodiments of this invention. The MOSFET devices 100-1 and 100-2 have similar cell configuration as that shown in FIG. 2A. Both of these devices 100-1 and 100-2 have thick oxide insulation layer 145 to insulate the Zener diode from the p-type doped region 125 underneath the thin gate oxide layer 115. In FIG. 3A, the contact openings to the source 130 and the gate 120 are open through the BPSG protective layer 135 as trenches. The contact trenches are then filled with tungsten plugs 170 and 180 to contact the source and gate respectively. Contact plugs 170-Z and 180-Z are filled in the trenches to contact the Zener diode to electrically connected to the source and gate respectively. A barrier layer of Ti/TiN surrounds the tungsten plugs 170, 180, 170-Z and 180-Z in these contact trenches. In FIG. 3B, the contact trenches are opened in the n-type doped regions 155 in the Zener diode to reach the thick oxide layer 145. The contact trenches to the Zener diode are filled with tungsten plugs 170-Z′ and 180-Z′ reaches down to the thick oxide layer 145. These contact plugs 170′ and 180′ can avoid gate/source short due to silicon over etch through the Zener polysilicon layer 150. FIGS. 3 and 4 are two top views for illustrating the closed stripes for the contact plugs 170-Z and 180-Z or 170-Z′ and 180-Z′ as that shown in FIGS. 3A and 3B respectively. In FIG. 5, open stripes are implemented to avoid corner weakness due to strong electrical fields formed near the corner spots of the metal contact stripes. The trenched contact plugs for contact the Zener diode to carry out the ESD protection function is formed simultaneously when the trenched contact plugs formed in source area. It provides good metal step coverage over small contact area. The open or close stripe design is better than discontinuous square or rectangular since the ESD capability is proportional to contact length or peripheral. The stripe contact plug configurations as shown in FIGS. 4 and 5 thus significantly improve the EDS protection capabilities of the semiconductor power devices.

FIG. 6A shows an equivalent circuit of FIG. 3A or 3B with the Zener diode connected between the gate electrode 160 via the n-doped region 155-G and source electrode 140 via the n doped region 155-S. The Zener diode is connected between the gate electrode 160 via the n-doped region 155-G and source electrode 140 via the n doped region 155-S. Furthermore, the trenched gate contact plug 180-G is connected to a n+ doped regions as resistor R. The trenched gate connect plug 180G is further connected to the gate metal 160. FIG. 6B is an equivalent circuit of FIG. 6C. FIG. 6D is an equivalent circuit of FIG. 6E. FIG. 6E is a top view. A resistor R implemented as n+ doped region is in series connection with two Zener diodes D1 and D2, providing good ESD protection. Electrostatic charge will go to the left Zener diode D1 first since the resistor slow down the electrostatic charge the goes through gate and right Zener diode. Once the left Zener diode D1 burn out, the electrostatic charge then goes through the right Zener diode D2 for second protection of gate oxide. The circuit structures shown in FIGS. 6D and 6E provide better protection than those of FIGS. 6A to 6B and 6C to 6D which have only have one Zener diode.

Referring to FIGS. 7A to 7F for a serial of side cross sectional views to illustrate the fabrication steps of a MOSFET device as that shown in FIG. 2A. In FIG. 7A, a trench mask (not shown) is applied to open a plurality of trenches 208 in an epitaxial layer 210 supported on a substrate 205 by employing a dry silicon etch process. In the termination area, a wider trench 208's is also formed. In FIG. 7B, an oxidation process is performed to form an oxide layer covering the trench walls. The trench is oxidized with a sacrificial oxide to remove the plasma damaged silicon layer during the process of opening the trench. Then an oxide layer 215 is grown followed by depositing a polysilicon layer 220 to fill the trench and covering the top surface and then doped with an N+ dopant. The polysilicon layer 220 and 220′ filling the wider trench 208′ are either etched back or removed by applying a chemical mechanical planarization process (CMP) to remove the polysilicon above the top surface. The manufacturing process proceeds with a P-body implant with a P-type dopant. Then an elevated temperature is applied to diffuse the P-body 225 into the epitaxial layer 210.

In FIG. 7C, the processes continues with the deposition of a thick oxide layer 245. The thickness of the thick oxide layer is greater than one thousand Angstroms. A polysilicon layer 250 is then deposited on top of the thick oxide layer 245 followed by a p-type ion implantation with a blank boron ion implant process. Referring to FIG. 7D, a photo resist 252 is applied as a polysilicon mask to carry out a polysilicon etch followed by a dry oxide etching process to etch the thick oxide layer 245. Referring FIG. 7E, the photoresist 252 is removed. A source mask 254 is applied to carry out a source ion implantation to form the source regions 230 and several N+ regions 255 adjacent to the p-doped regions 250 thus forming the zener diode. In FIG. 7F, the source mask 254 is removed and an BPSG insulation layer 235 is formed over the top and a contact mask (not shown) is applied to open the contact openings to the gate 220′ and the source 230. A metal layer is deposited followed by applying a metal mask (not shown) to pattern the metal layer into the source metal contact 240 and the gate metal contact 260.

FIGS. 7G and 7H are two cross sectional views for illustrating the processing steps to form the MOSFET device shown in FIG. 3A. In FIG. 7F, an oxide deposition is carried out to form the oxide protective layer 235. A contact mask (not shown) is employed to open a plurality of contact openings 268 for the source contact and 278 for the gate contact. There are also contact openings 268-Z and 278-Z opened above the Zener diode for establishing electrical contact with the source and the gate respectively. Then a boron ion dopant implant is performed to form the p+ contact resistance regions 248 below the contact openings. In FIG. 7H, Ti/TiN are filled into the contact open trenches. Then the contact plugs composed of tungsten are filled into the trenched contact openings. The contact plugs 270 and 270-Z are formed to contact the source regions 230. The contact plugs 280 and 280-Z are formed to contact the gate 220. A tungsten etch back is performed followed by a metal layer formation. A metal mask (not shown) is applied to pattern the metal layer into a source metal 240 and a gate metal layer 260. The source metal 240 is in electrical contact with the trenched source contact plugs 270 and 270-Z. The gate metal 260 is in electrical contact with the trenched gate contact plug 280 and 280-Z.

According to the above drawings and descriptions, this invention further discloses a method for providing an ESD protection to a semiconductor power device by implementing a Zener diode. The method includes a step of disposing the Zener diode on a thick insulation layer for completely insulating the Zener diode from a doped region of a dopant ions of the semiconductor power device whereby the Zener diode is substantially insulated from a doped region below the thick insulation layer for eliminating a channel effect between two terminals of the Zener diode disposed above the doped region. In an alternate preferred embodiment, the step of disposing the Zener diode on the thick insulation layer includes a step of forming the thick oxide layer having a thickness substantially greater than five hundred (500) Angstroms. In another preferred embodiment, the method further includes a step of forming the Zener diode with a multiple doped regions having at least a middle region doped with a first conductivity type disposed between two regions doped with a second conductivity type. In another preferred embodiment, the method further includes a step of forming the Zener diode with a doped region of a second conductivity type disposed between two doped regions of a first conductivity type and connecting one of the two doped regions to a source metal and connecting another one of the doped regions to a gate metal of the power semiconductor device. In another preferred embodiment, the method further includes a step of forming an overlying insulation layer for covering the semiconductor power device and the Zener diode and opening in the overlying insulation layer a plurality of contact openings and filling at least two of the contact openings with a source metal to contact a source region and a first terminal of the Zener diode. The method further includes a step of filling at least one of the contact openings with a gate metal for contacting to a gate and to a second terminal of the Zener diode. In another preferred embodiment, the method further includes a step of forming an overlying insulation layer for covering the semiconductor power de vice and the Zener diode and opening in the overlying insulation layer a plurality of trenches penetrating thought the overlying insulation layer and filling the trenches with trenched contact plugs with some of the contact plugs in electrical contact with a source region and a source metal and a first terminal of the Zener diode and with other of the trenched plugs in electric contact with a gate and a gate metal and also with a second terminal of the Zener diode. In another preferred embodiment, the step of forming the trenched contact plug includes a step of forming the trenched contact plugs as tungsten contact plugs. In another preferred embodiment, the step of forming the trenched contact plug includes a step of forming the trenched contact plugs as tungsten contact plugs surrounded by a Ti/TiN barrier layer. In another preferred embodiment, the step of forming the trenched contact plug includes a step of forming the contact plugs as an extended continuous contact plug constituting a closed stripe contact plug. In another preferred embodiment, the step of forming the trenched contact plug includes a step of forming the contact plugs as at least one extended continuous contact plugs constituting open stripes. In another preferred embodiment, the method further includes a step of forming the Zener diode with a p-type doped region disposed between two n-type doped regions and connecting one of the n-type doped regions to the source metal and connecting another of the n-type doped regions to the gate metal of the semiconductor power device. In another preferred embodiment, the method further includes a step of forming a doped region electrically connected between the Zener diode and the gate metal for serving a resistor function for slowing down an ESD current charge flow through a gate of the semiconductor power device. In another preferred embodiment, the method further includes a step of disposing an additional Zener diode as a second Zener diode on the thick insulation layer connecting to the Zener diode as a first Zener diode whereby the second Zener diode serving an extra ESD protection for the semiconductor power device to receive ESD charges after the first Zener diode is burnt out by the ESD charges. In another preferred embodiment, the method further includes a step of forming a doped region for electrically connecting between the first Zener diode and the second Zener diode and electrically connecting to the gate metal for serving a resistor function for slowing down an ESD current charge flow through a gate of the semiconductor power device. In another preferred embodiment, the step of forming the Zener diode further includes a step of forming the Zener diode with an array of doped regions includes doped regions doped alternately with a first conductivity type and a second conductivity type with a first and last doped regions doped with a first conductivity type. In another preferred embodiment, the step of forming the Zener diode further includes a step of forming the Zener diode with an array of doped regions includes doped regions arranged as N+PN+PN+ regions. In another preferred embodiment, the step of forming the Zener diode further includes a step of forming the Zener diode with an array of doped regions includes doped regions arranged as N+PN+PN+PN+ regions.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

1. A semiconductor power device comprising a Zener diode connected between a gate metal and a source metal of said MOSFET device for providing an electrostatic discharge (ESD) protection, said semiconductor power device further comprising:
a thick insulation layer with a thickness greater than gate oxide for completely insulating said Zener diode from a doped region of body dopant ions whereby said Zener diode is substantially insulated from a doped region below said thick insulation layer for eliminating a channel effect between two terminals of said Zener diode disposed above said doped region.

2. The semiconductor power device of claim 1 wherein:
said thick insulation layer comprising a thick oxide layer having a thickness substantially greater than five hundred (500) Angstroms.

3. The semiconductor power device of claim 1 wherein:
said thick insulation layer comprising a separately formed thick insulation layer on top of a gate oxide layer.

4. The semiconductor power device of claim 1 wherein:
said Zener diode further comprising multiple doped regions having at least a middle region doped with a first conductivity type disposed between two regions doped with a second conductivity type.

5. The semiconductor power device of claim 1 further comprising:
said Zener diode further comprising a doped region of a second conductivity type disposed between two doped regions of a first conductivity type wherein one of said two doped regions connected to said source metal and another one of said two doped regions connected to said gate metal of said semiconductor power device.

6. The semiconductor power device of claim 1 further comprising:
an overlying insulation layer covering said semiconductor power de vice and said Zener diode wherein said overlying insulation layer having a plurality of contact openings having at least two of said contact openings filled with said source metal to contact a source region and a first terminal of said Zener diode; and
at least one of said contact openings filled with said gate metal for contacting to a gate and a second terminal of said Zener diode.

7. The semiconductor power device of claim 1 further comprising:
an overlying insulation layer covering said semiconductor power device and said Zener diode wherein said overlying insulation layer having a plurality of trenched contact plugs disposed in trenches penetrating through said insulation layer wherein some of said contact plugs are in electrical contact with a source region and said source metal and a first terminal of said Zener diode and other of said trenched plugs are in electric contact with a gate and said gate metal and also with a second terminal of said Zener diode.

8. The semiconductor power device of claim 7 wherein:
said trenched contact plugs further comprising tungsten contact plugs.

9. The semiconductor power device of claim 7 wherein:
said trenched contact plugs further comprising tungsten contact plugs surrounded by a Ti/TiN barrier layer.

10. The semiconductor power device of claim 7 wherein:
said trenched contact plugs further comprising an extended continuous contact plug constituting a closed stripe contact plug.

11. The semiconductor power device of claim 7 wherein:
said trenched contact plugs further comprising at least one extended continuous contact plugs constituting open stripes.

12. The semiconductor power device of claim 1 wherein:
said Zener diode further comprising a p-type doped region disposed between two n-type doped regions wherein one of said n-type doped regions connected to said source metal and another of n-type doped regions connected to said gate metal of said semiconductor power device.

13. The semiconductor power device of claim 1 further comprising:
a doped region electrically connected between said Zener diode and said gate metal serving a resistor function for slowing down an ESD current charge flow through a gate of said semiconductor power device.

14. The semiconductor power device of claim 1 wherein:
said semiconductor power device further comprising a metal oxide semiconductor field effect transistor (MOSFET) device.

15. The semiconductor power device of claim 1 further comprising:
an additional Zener diode as a second Zener diode disposed also on said thick insulation layer as said Zener diode as a first Zener diode wherein said second Zener diode serving an extra ESD protection for said semiconductor power device to receive ESD charges after said first Zener diode is burnt out by said ESD charges.

16. The semiconductor power device of claim 14 further comprising:
a doped region electrically connected between said first Zener diode and said second Zener diode and electrically connecting to said gate metal serving a resistor function for slowing down an ESD current charge flow through a gate of said semiconductor power device.

17. The semiconductor power device of claim 1 wherein:
said Zener diode further comprising an array of doped regions comprising doped regions doped alternately with a first conductivity type and a second conductivity type with a first and last doped regions doped with a first conductivity type.

18. The semiconductor power device of claim 1 wherein:
said Zener diode further comprising an array of doped regions comprising doped regions arranged as N+PN+PN+ regions.

19. The semiconductor power device of claim 1 wherein:
said Zener diode further comprising an array of doped regions comprising doped regions arranged as N+PN+PN+PN+ regions.

20. A method for providing an ESD protection to a semiconductor power device by implementing a Zener diode comprising:
disposing said Zener diode on a thick insulation layer for completely insulating said Zener diode from a doped region of a dopant ions of said semiconductor power device whereby said Zener diode is substantially insulated from a doped region below said thick insulation layer for eliminating a channel effect between two terminals of said Zener diode disposed above said doped region.

21. The method of claim 20 wherein:
said step of disposing said Zener diode on said thick insulation layer comprising a step of forming said thick oxide layer having a thickness substantially greater than five hundred (500) Angstroms.

22. The method of claim 20 wherein:
said step of disposing said Zener diode on said thick insulation layer comprising a step of separately forming said thick insulation layer on top of a gate oxide layer.

23. The method of claim 20 further comprising:
forming said Zener diode with a multiple doped regions having at least a middle region doped with a first conductivity type disposed between two regions doped with a second conductivity type.

24. The method of claim 20 further comprising:
forming said Zener diode with a doped region of a second conductivity type disposed between two doped regions of a first conductivity type and connecting one of said two doped regions to a source metal and connecting another one of said doped regions to a gate metal of said power semiconductor device.

25. The method of claim 20 further comprising:
forming an overlying insulation layer for covering said semiconductor power de vice and said Zener diode and opening in said overlying insulation layer a plurality of contact openings and filling at least two of said contact openings with a source metal to contact a source region and a first terminal of said Zener diode; and
filling at least one of said contact openings with a gate metal for contacting to a gate and to a second terminal of said Zener diode.

26. The method of claim 20 further comprising:
forming an overlying insulation layer for covering said semiconductor power de vice and said Zener diode and opening in said overlying insulation layer a plurality of trenches penetrating thought said overlying insulation layer and filling said trenches with trenched contact plugs with some of said contact plugs in electrical contact with a source region and a source metal and a first terminal of said Zener diode and with other of said trenched plugs in electric contact with a gate and a gate metal and also with a second terminal of said Zener diode.

27. The method of claim 26 wherein:
said step of forming said trenched contact plug comprising a step of forming said trenched contact plugs as tungsten contact plugs.

28. The method of claim 26 wherein:
said step of forming said trenched contact plug comprising a step of forming said trenched contact plugs as tungsten contact plugs surrounded by a Ti/TiN barrier layer.

29. The method of claim 26 wherein:
said step of forming said trenched contact plug comprising a step of forming said contact plugs as an extended continuous contact plug constituting a closed stripe contact plug.

30. The method of claim 26 wherein:
said step of forming said trenched contact plug comprising a step of forming said contact plugs as at least one extended continuous contact plugs constituting open stripes.

31. The method of claim 20 further comprising:
forming said Zener diode with a p-type doped region disposed between two n-type doped regions and connecting one of said n-type doped regions to said source metal and connecting another of said n-type doped regions to said gate metal of said semiconductor power device.

32. The method of claim 20 further comprising:
forming a doped region electrically connected between said Zener diode and said gate metal for serving a resistor function for slowing down an ESD current charge flow through a gate of said semiconductor power device.

33. The method of claim 20 further comprising:
disposing an additional Zener diode as a second Zener diode on said thick insulation layer connecting to said Zener diode as a first Zener diode whereby said second Zener diode serving an extra ESD protection for said semiconductor power device to receive ESD charges after said first Zener diode is burnt out by said ESD charges.

34. The method of claim 33 further comprising:
forming a doped region for electrically connecting between said first Zener diode and said second Zener diode and electrically connecting to said gate metal for serving a resistor function for slowing down an ESD current charge flow through a gate of said semiconductor power device.

35. The method of claim 20 wherein:
said step of forming said Zener diode further comprising a step of forming said Zener diode with an array of doped regions comprising doped regions doped alternately with a first conductivity type and a second conductivity type with a first and last doped regions doped with a first conductivity type.

36. The method of claim 20 wherein:
said step of forming said Zener diode further comprising a step of forming said Zener diode with an array of doped regions comprising doped regions arranged as N+PN+PN+ regions.

37. The method of claim 20 wherein:
said step of forming said Zener diode further comprising a step of forming said Zener diode with an array of doped regions comprising doped regions arranged as N+PN+PN+PN+ regions.
